(19) United States
(12) Patent Application Publication
(10) Pub. No.: US 2013/0033806 A1
(43) Pub. Date: Feb. 7, 2013

(54) CASE FOR MOBILE ELECTRONIC DEVICES

(71) Applicant: Christoph M. Rochna, Augsburg (DE)

(72) Inventor: Christoph M. Rochna, Augsburg (DE)

(73) Assignee: Gellyfish Technology of Texas, LLC

(21) Appl. No.: 13/562,912

(22) Filed: Jul. 31, 2012

Related U.S. Application Data
(60) Provisional application No. 61/513,873, filed on Aug. 1, 2011.

(51) Int. Cl. H05K 5/00

(52) U.S. Cl. 361/679.01

(57) ABSTRACT

A case for a mobile electronic device includes a primary body member having an upper surface and a bottom surface. The body member includes a long axis and a short axis with an upper edge, a lower edge, a first lateral edge, and second lateral edge. The body member further includes a first, second, third and a fourth bend line extending between the first lateral edge and the second lateral edge, The first, second, third and fourth bend lines divide the body member into a first section, a second section, a third section, a fourth section and fifth section that cover and wrap about the mobile electronic device when the case is wrapped about the mobile electronic device. An adhesive strip is secured to the upper surface of the body member in the area of the fifth section.

### CROSS REFERENCE TO RELATED APPLICATION

This application claims the benefit of U.S. Provisional Application Ser. No. 61/513,873, entitled CASE FOR MOBILE ELECTRONICS, filed Aug. 1, 2011.

### BACKGROUND OF THE INVENTION

1. Field of the Invention

The invention relates to protective cases and covers for mobile electronic devices. More particularly, the invention relates to cases and covers that are attached to the mobile device by use of stretch-release adhesive.

2. Description of the Related Art

Although cases and covers attach to mobile devices by means of embracing or enclosing the mobile device, they do not provide users with a solution that eliminates foreign material covering at least some part or area of the mobile device. While traditional cases and covers for mobile electronic devices provide a protective enclosure, they exhibit some key problems.

There are some cases for mobile electronic devices that are in their appearance and function identical to a sleeve or bag. The user has to remove the mobile electronic device from the case completely in order to access and use the mobile electronic device. This operation usually requires several steps; for example, opening the case, pulling the mobile electronic device out of its enclosure and, after having used the mobile electronic device, inserting the mobile electronic device into the case and closing the case. Procedures such as this leave the mobile electronic device exposed while it is removed from its case.

Other cases or covers for mobile electronic devices either completely enclose the mobile electronic device with a transparent plastic sleeve or partially enclose the mobile electronic device within a rigid plastic frame. In both cases the mobile electronic device can be accessed without the need to remove it from its case, but the full or partial enclosure of the mobile electronic device impacts on the usability and visual appeal of the mobile electronic device.

The complete enclosure with a transparent plastic sleeve, for instance, impacts in the haptic quality of the interaction with the mobile electronic device by reducing force-feedback when pressing the buttons of the mobile electronic device through the transparent plastic.

Furthermore, the transparent plastic enclosure often becomes brittle and partially opaque due to wear and tear. The transparent plastic enclosures also tend to collect dirt and dust in areas which are less touched by the user.

A rigid plastic frame, in contrast, leaves most parts of the mobile electronic device exposed and, therefore, overcomes some of the above mentioned problems. The rigid plastic frame, however, is visible from all sides of the mobile electronic device (because it needs to “grab” the mobile electronic device in some way) and therefore has a negative visual effect on the mobile electronic device.

Another problem of the rigid plastic frame is its need to firmly fit around the mobile electronic device and, therefore, is suitable only for one specific model; it cannot accommodate a mobile electronic device with a slight dimensional difference. This means that a retailer of such cases needs to offer a broad range of cases, each suitable for one specific mobile electronic device.

A problem of both the transparent plastic enclosure and the rigid plastic frame model is the relative complexity of the product: in both instances the case is composed of an outer cover attached to a precisely dimensioned contraption to attach to the mobile electronic device, which requires different tooling for each model of the mobile electronic device (in the case of the rigid plastic frame, one particular and expensive injection molding tool is required for the IPhone® (mobile smart phone), another one for the Blackberry® (mobile smart phone), a third one for the Android® (mobile smart phone).

Mobile electronic devices are transported, carried and used everywhere and prone to be damaged when dropped, scratched or exposed to the environment. Usually these mobile electronic devices are expensive to acquire or replace. Therefore users tend to carry such mobile electronic devices in protective cases or covers. On the other hand users do not want such protective covers or cases to impact on the functionality/usability of the mobile electronic device, nor do they want the cover or case to have a negative visual impact on their mobile electronic device (also because of the social status such device can cast on the user).

As such, the present invention has been developed to provide a mechanism for attaching a mobile electronic device to a case or cover which does not require a transparent plastic enclosure or a rigid plastic frame or any sort of customized contraption. The present invention utilizes stretch-release adhesive in combination with a protective case to attach a mobile electronic device to a case or cover. The inventive mechanism permits the mobile electronic device to be attached to a case without any visible contraption that may have a negative physical or visual impact on the mobile electronic device. The stretch-release adhesive securely attaches to the mobile electronic device and, if desired, can be removed without damage to either the surface of the mobile electronic device or the case (as other adhesives would do).

### SUMMARY OF THE INVENTION

It is, therefore, an object of the present invention to provide a case for a mobile electronic device. The case includes a primary body member having an upper surface and a bottom surface. The body member includes a long axis and a short axis with an upper edge, a lower edge, a first lateral edge, and second lateral edge. The body member further includes a first bend line, a second bend line, a third bend line and a fourth bend line extending between the first lateral edge and the second lateral edge. The first, second, third and fourth bend lines divide the body member into a first section, a second section, a third section, a fourth section and a fifth section that cover and wrap about the mobile electronic device when the case is wrapped about the mobile electronic device. The first section extends from the upper edge to the first lateral bend line along the long axis, the second section extends from the first lateral bend line to the second lateral bend line along the long axis, the third section extends from the second lateral bend line to the third lateral bend line along the long axis, the fourth section extends from the third lateral bend line to the fourth lateral bend line along the long axis, and the fifth section extends from the fourth lateral bend line to the lower edge along the long axis. An adhesive strip is secured to the upper surface of the body member in the area of the fifth section.

It is also an object of the present invention to provide a case wherein the second section is shaped and dimensioned to wrap about a first edge of the mobile electronic device when the case is wrapped about the mobile electronic device.

It is another object of the present invention to provide a case wherein the third section is shaped and dimensioned to fit over the upper surface of the mobile electronic device when the case is wrapped about the mobile electronic device.

It is a further object of the present invention to provide a case wherein the fourth section is shaped and dimensioned to wrap about the second edge of the mobile electronic device when the case is wrapped about the mobile electronic device.

It is also an object of the present invention to provide a case wherein the fifth section is shaped and dimensioned to support the base of the mobile electronic device when the case is wrapped about the mobile electronic device

It is another object of the present invention to provide a case wherein the adhesive strip is a stretch-release adhesive strip.

It is a further object of the present invention to provide a case wherein a back side of the stretch-release adhesive strip is secured to the upper surface of the body member.

It is also an object of the present invention to provide a case wherein the back of the mobile electronic device may be secured to an exposed upper surface of the stretch-release adhesive strip, and when it is time to remove the mobile electronic device from the case, a free end of the stretch-release adhesive strip is engaged and stretched in the direction of the long axis resulting in the release of the back surface of the mobile electronic device from the stretch-release adhesive strip and ultimately the fifth section.

Other objects and advantages of the present invention will become apparent from the following detailed description when viewed in conjunction with the accompanying drawings, which set forth certain embodiments of the invention.

### BRIEF DESCRIPTION OF THE DRAWINGS

FIG. 1 is an exploded view of a case in accordance with the present invention with the stretch-release adhesive behind the mobile electronic device visible.

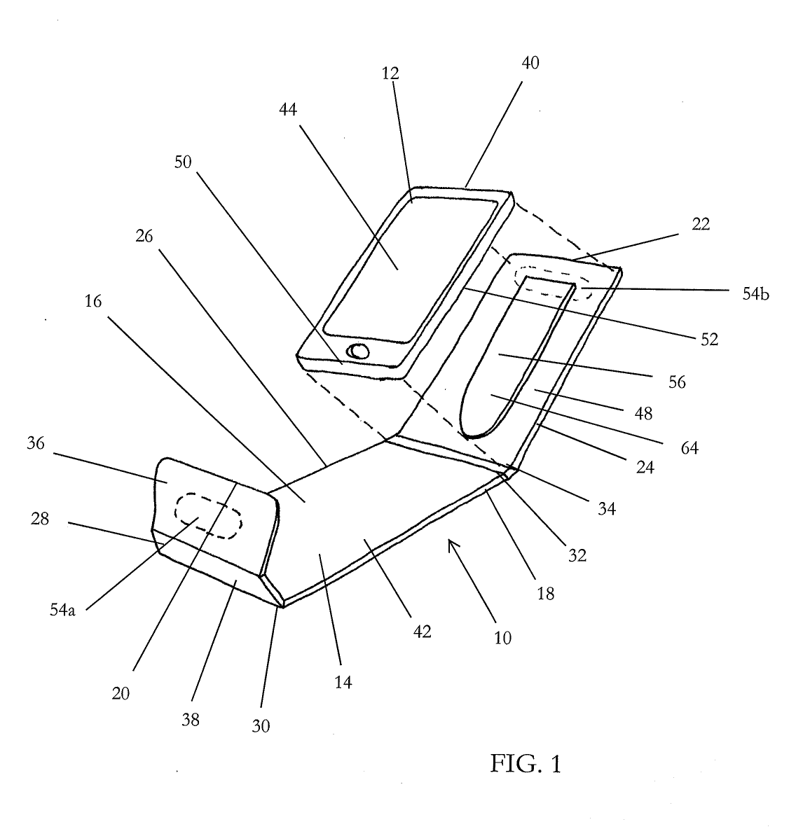

FIG. 2 is a section view of the case in accordance with the present invention including the mobile electronic device.

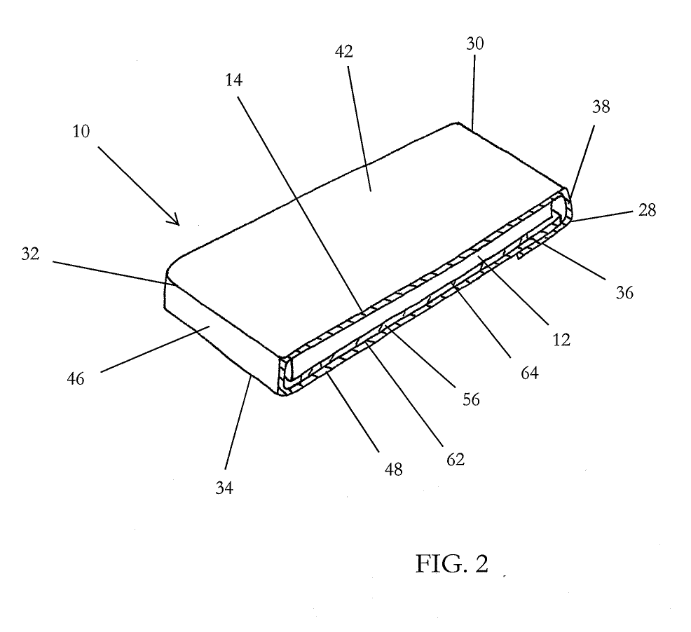

FIG. 3 is a detailed section view of the stretch-release adhesive sandwiched in-between the mobile electronic device and the case showing how pulling upon the stretch-release adhesive will result in the release of the mobile electronic device.

FIG. 4 is an exploded view of a case in accordance with an alternate embodiment of the present invention.

### DESCRIPTION OF THE PREFERRED EMBODIMENT

The detailed embodiment of the present invention is disclosed herein. It should be understood, however, that the disclosed embodiment is merely exemplary of the invention, which may be embodied in various forms. Therefore, the details disclosed herein are not to be interpreted as limiting, but merely as a basis for teaching one skilled in the art how to make and/or use the invention.

In accordance with the present invention, and with reference to the various figures disclosed herein, a case 10 for a mobile electronic device 12 is disclosed. While the present case 10 is disclosed as being adapted for use in conjunction with a touchscreen type mobile electronic device, for example, an IPhone®, it is appreciated the present case 10 may be used in conjunction with other mobile electronic devices requiring similar protection.

The case 10 includes a primary body member 14. The body member 14, when lying flat upon a horizontal surface, is substantially rectangular with an upper surface 16 and a bottom surface 18. The body member 14 is relatively thin (that is, thick enough to provide the desired level of protection, but thin enough to be aesthetically pleasing) and the thickness thereof constitutes the distance between the bottom surface 18 and the upper surface 16. In accordance with a preferred embodiment, the case 10 is made from at least two materials, including one material specified to provide strength and structural rigidity for the case and one flexible material used to bend and wrap around the exterior of the mobile electronic device. It is anticipated that natural and environmentally friendly materials will be used, for example, paper composites and natural fabrics such as hemp would provide ideal materials for the manufacture of the present body member. Other materials such as leather, synthetic leather, plastics or other composites may also be used to provide the proper protection and durability. It is appreciated other materials with similar characteristics may be used without departing form the spirit of the present invention.

With its rectangular shape, the body member 14 includes a long axis and a short axis with an upper edge 20, a lower edge 22, a first lateral edge 24, and second lateral edge 26. The body member 14 is provided with four lateral bend lines 28, 30, 32, 34 extending between the first lateral edge 24 and the second lateral edge 26. The four lateral bend lines 28, 30, 32, 34 divide the body member 14 into multiple sections that cover and wrap about the mobile electronic device 12 when the case 10 is wrapped about the mobile electronic device 12. It is appreciated the four lateral bend lines 28, 30, 32, 34 are flexible allowing pivoting between adjacent body section, and the bend lines therefore may be considered joints. As such, and in accordance with a preferred embodiment, the four lateral bend lines (or joints) 28, 30, 32, 34 are defined or made by creases formed in the a flexible material from which the body member 14 is formed. In particular, the first section, that is, the coupling section 36, extends from the upper edge 20 to the first lateral bend line 28 along the long axis. Extending from the first lateral bend line 28 to the second lateral bend line 30 along the long axis is the second section, or first hinge section 38. The first hinge section 38 is shaped and dimensioned to wrap about a first edge 40 of the mobile electronic device 12 when the case 10 is wrapped about the mobile electronic device 12. Extending from the second lateral bend line 30 to the third lateral bend line 32 along the long axis is the third section, or cover section 42. The cover section 42 is shaped and dimensioned to fit over the upper surface (for example, the interface screen) 44 of the mobile electronic device 12 when the case 10 is wrapped about the mobile electronic device 12. Extending from the third lateral bend line 32 to the fourth lateral bend line 34 along the long axis is the fourth section, or second hinge section 46. The second hinge section 46 is shaped and dimensioned to wrap about the second edge 50 of the mobile electronic device 12 when the case 10 is wrapped about the mobile electronic device 12. Extending from the fourth lateral bend line 34 to the lower edge 22 along the long axis is the fifth section, or base section 48. The base section 48 is shaped and dimensioned to support the base 52 of the mobile electronic device 12 when the case 10 is wrapped about the mobile electronic device 12.

When it is desired to protect the mobile electronic device 12 within the case 10, the coupling section 36 is pulled over the interface screen 44 of the mobile electronic device 12, around the first edge 40 of the mobile electronic device 12 and the lower edge 22 of the body member 14. At this point the upper surface 16 of the body member 14 at the coupling section 36 is in facing relationship with the bottom surface 18 of the body member 14 at the base section 48 adjacent the lower edge of the body member 14, and the first hinge section 38 is wrapped about the first edge 40 of the mobile electronic device 12 and the second hinge section 38 is wrapped about the second edge 50 of the mobile electronic device 12. With the coupling section 36 facing the base section 48, the coupling section 36 is secured thereto. In accordance with a preferred embodiment, magnets 54a, 54b are secured within the coupling section 36 and the base section 48 for facilitating selectively releasable attachment of the coupling section to the base section. When it is desired to access the mobile electronic device 12, the coupling section 36 is detached from the base section 48 and the case 10 is opened.

In order to ensure secure attachment of the mobile electronic device 12 to the base section 48, the upper surface 16 of the body member 14 in the area of the base section 48 is provided with a stretch adhesive material in the form of a stretch-release adhesive strip 56 (that is, the stretch-release adhesive strip 56 is positioned within the base section 48), the back side 62 of which is secured to the upper surface 16 of the body member 14. The stretch-release adhesive strip 56 is of a pre-formed shape designed to match the dimensions of the mobile electronic device 12. It is appreciated stretch-release adhesives are adhesive tapes which can be cleanly removed from a surface by stretching the tape to actuate clean removal from the material to which it is bound. Such adhesives are disclosed in U.S. Pat. Nos. 5,516,581 and 6,106,937, which are incorporated herein by reference. For example, it is appreciated TESA Powerstrips®, stretch-release adhesive strip or 3M Command® products may be used in accordance with the present invention. Briefly, these stretch-release adhesives come in a strip form and include a highly extensible and substantially inelastic backing and a layer of pressure sensitive adhesive. When applied to a support surface, the adhesive tape strip becomes firmly bonded thereto, but can be easily removed without damaging the support surface by simply stretching the tape.

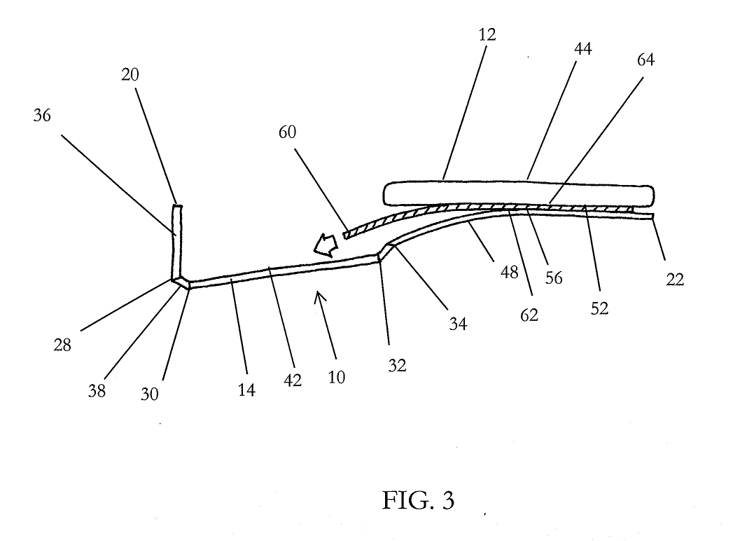

In this way, the back of the mobile electronic device 12 may be secured to the exposed upper surface 64 of the stretch-release adhesive strip 56, and ultimately the body member 14 by simply pressing it downwardly upon the base section 48. When it is time to remove the mobile electronic device 12 from the case 10, the free end 60 of the stretch-release adhesive strip 56, which is adhesively coupled to neither the back of the mobile electronic device 12 of the upper surface 16 of the body member 14, is engaged and stretched in the direction of the long axis (see FIG. 3). This will result in the release of the back surface 52 of the mobile electronic device 12 from the stretch-release adhesive strip 56 and ultimately the base section 48.

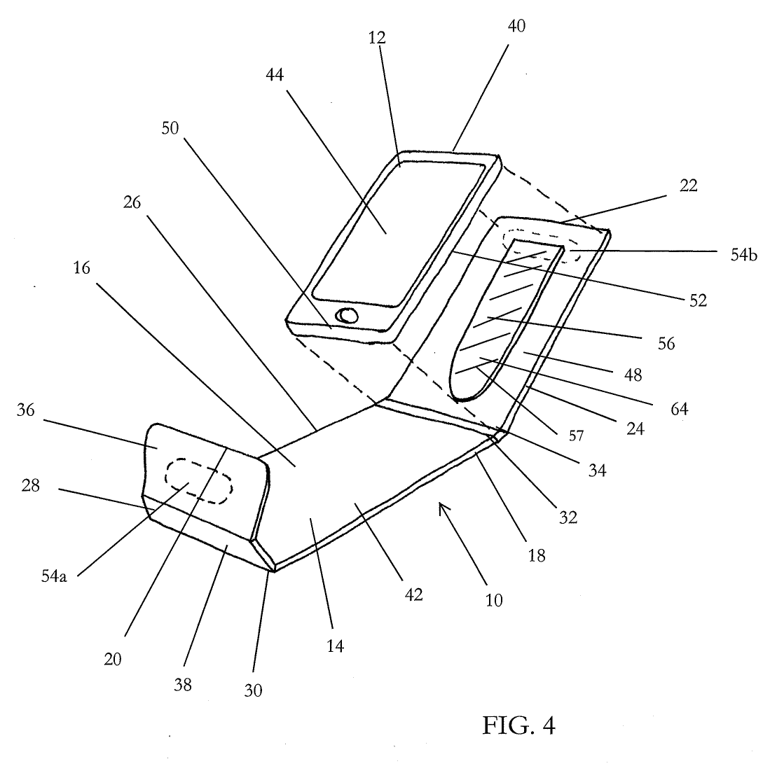

It is also anticipated that other shapes of stretch adhesive materials, in addition to the commonly produced strips, may be utilized. The stretch adhesive material may be formed or cut into a shape to more precisely match the shape of the electronic device. Furthermore, and with reference to the embodiment disclosed in FIG. 4, the stretch-release adhesive strip 56 may contain cuts or breaks 57 in portions of the adhesive material while the remaining elements of the case remain the same. In this way it would be possible to avoid the use of a pull tab. The mobile electronic device 12 could be removed from the stretch-release adhesive strip 56 via a twisting motion that would effectively break the bond of the stretch-release adhesive strip 56 given the cuts or breaks 57 in the material.

The present invention resolves a concrete and significant disadvantage of existing cases or covers for electronic devices by using stretch-release adhesive instead of mechanical mechanisms for attaching the mobile electronic device to the case. Almost anyone who uses a mobile phone, mp3-player or similar is—at least at some stage—worried that he might drop or damage the mobile electronic device in one or the other way and therefore longs to put in place some type of protective cover. Usually a mobile electronic device appeals to its user prior to the purchase due to its over-all appearance, haptic quality and/or visual style. Some or all of those initial triggers of appeal are lost if the mobile electronic device is covered and buried in or under some clear plastic cover or partially hidden within a skeleton of a rigid plastic frame. The present invention provides a mechanism to produce a case or cover that protects a mobile electronic device in transit, but does not interfere with the haptics or the appearance of such mobile electronic device. The present invention allows the user to protect his/her device without significant impact on either visual appearance or haptic experience.

While the preferred embodiments have been shown and described, it will be understood that there is no intent to limit the invention by such disclosure, but rather, is intended to cover all modifications and alternate constructions falling within the spirit and scope of the invention.

1. A case for a mobile electronic device, comprising:
a primary body member having an upper surface and a bottom surface, the primary body member includes a long axis and a short axis with an upper edge, a lower edge, a first lateral edge, and second lateral edge, the primary body member further includes a first lateral bend line, a second lateral bend line, a third lateral bend line and a fourth lateral bend line extending between the first lateral edge and the second lateral edge, the first, second, third and fourth lateral bend lines divide the primary body member into a first section, a second section, a third section, a fourth section and fifth section that cover and wrap about the mobile electronic device when the case is wrapped about the mobile electronic device;
the first section extends from the upper edge to the first lateral bend line along the long axis;
the second section extends from the first lateral bend line to the second lateral bend line along the long axis;
the third section extends from the second lateral bend line to the third lateral bend line along the long axis;
the fourth section extends from the third lateral bend line to the fourth lateral bend line along the long axis;
the fifth section extends from the fourth lateral bend line to the lower edge along the long axis;
an adhesive strip is secured to the upper surface of the primary body member in the fifth section.

2. The case according to claim 1, wherein the second section is shaped and dimensioned to wrap about a first edge of the mobile electronic device when the case is wrapped about the mobile electronic device.

3. The case according to claim 1, wherein the third section is shaped and dimensioned to fit over the upper surface of the mobile electronic device when the case is wrapped about the mobile electronic device.

4. The case according to claim 1, wherein the fourth section is shaped and dimensioned to wrap about a second edge of the mobile electronic device when the case is wrapped about the mobile electronic device.

5. The case according to claim 1, wherein the fifth section is shaped and dimensioned to support a base of the mobile electronic device when the case is wrapped about the mobile electronic device.

6. The case according to claim 1, wherein the adhesive strip is a stretch-release adhesive strip.

7. The case according to claim 6, wherein a back side of the stretch-release adhesive strip is secured to the upper surface of the primary body member.

8. The case according to claim 7, wherein the back of the mobile electronic device may be secured to an exposed upper surface of the stretch-release adhesive strip, and when it is time to remove the mobile electronic device from the case, a free end of the stretch-release adhesive strip is engaged and stretched in a direction of the long axis resulting in release of a back surface of the mobile electronic device from the stretch-release adhesive strip and ultimately the fifth section.

9. A case for a mobile electronic device, comprising:
a primary body member having an upper surface and a bottom surface shaped and dimensioned to fit around an electronic device utilizing bend lines or joints to wrap around edges of the electronic device and utilizing stretch adhesive material to attach the case to the mobile electronic device.

10. The case according to claim 9, wherein the bend lines or joints are made by creases in a flexible material.

11. The case according to claim 9, wherein the upper surface and the bottom surface of the case are made from paper, fabric, rubber or leather.

12. The case according to claim 9, wherein the upper surface and the bottom surface of the case are made from plastic.

13. The case according to claim 9, wherein the stretch adhesive material is a strip with a pull tab to release it from the electronic device.

14. The case according to claim 9, wherein the stretch adhesive material is a pre-formed shape designed to match the dimensions of the electronic device.

15. The case according to claim 9, wherein the stretch adhesive material is manufactured with cuts or breaks to eliminate the need for a pull tab by allowing the user to twist the device to activate the release of the adhesion.
